(19) United States
(12) Patent Application Publication
(10) Pub. No.: US 2009/0001352 A1
(43) Pub. Date: Jan. 1, 2009

(54) Non-Volatile Memory Device, Method of Manufacturing the Same, and Semiconductor Package

(75) Inventors: Jeong-hee Han, Gyeonggi-do (KR); Ji-Young Kim, Gyeonggi-do (KR); Chung-woo Kim, Gyeonggi-do (KR); Kang Long Wang, Santa Monica, CA (US); Siguang Ma, Los Angeles, CA (US)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/056,374

(22) Filed: Mar. 27, 2008

(30) Foreign Application Priority Data
Mar. 27, 2007 (KR) 10-2007-0030048

(51) Int. Cl. H01L 29/12; H01L 29/792; H01L 21/336

(52) U.S. Cl. 257/24; 257/324; 438/156; 257/E21.411; 257/E29.309; 257/E29.07

(57) ABSTRACT

Provided is a non-volatile memory device that can be highly integrated and may have a high reliability. Some embodiments of the non-volatile memory device include a first doping layer having a first conductivity on a substrate, a semiconductor pillar extending from the first doping layer on the substrate in an upward direction and having second conductivity opposite to the first conductivity, and a control gate electrode surrounding a sidewall of the semiconductor pillar. Embodiments of the non-volatile memory device may include a charge storage layer interposed between the semiconductor pillar and the control gate electrode and a second doping layer of the first conductivity that is disposed on the semiconductor pillar and is electrically connected to the semiconductor pillar.

### CROSS-REFERENCE TO RELATED PATENT APPLICATION

This application claims the benefit of Korean Patent Application No. 10-2007-0030048, filed on Mar. 27, 2007 in the Korean Intellectual Property Office, the disclosure of which is incorporated herein in its entirety by reference.

### BACKGROUND OF THE INVENTION

The present invention relates to semiconductor devices, and more particularly, to non-volatile memory devices and methods of manufacturing non-volatile memory devices.

Recently, large capacity mobile electronic devices such as digital cameras and/or MP3 players have garnered substantial interest. As the size of the electronic devices is increasingly reduced, a high capacity may also be desired. Such size reduction and demand for high capacity for these electronic devices may require a high integration degree and a high capacity of non-volatile memory devices used in these electronic devices.

However, the fabrication of highly integrated non-volatile memory devices via highly integrated patterns may be limited by the processing technology. Also, as the integration degree of conventional planar non-volatile memory devices may be limited, the performance thereof may decrease due to a short channel effect. Accordingly, a high integration of the conventional planar non-volatile memory devices may cause a decrease in reliability.

### SUMMARY OF THE INVENTION

Embodiments of the present invention include a non-volatile memory device that includes a first doping layer on a substrate, the first doping layer including a first conductivity, a semiconductor pillar that is configured to extend from the first doping layer on the substrate in an upward direction, the semiconductor pillar including a second conductivity that is substantially opposite the first conductivity and a control gate electrode surrounding a sidewall of the semiconductor pillar. Devices may further include a charge storage layer interposed between the semiconductor pillar and the control gate electrode and a second doping layer that is disposed on the semiconductor pillar and that is configured to be electrically connected to the semiconductor pillar, the second doping layer including the first conductivity.

In some embodiments, the first doping layer covers at least a central portion of a bottom surface of the semiconductor pillar. In some embodiments, the first doping layer surrounds a bottom surface of the semiconductor pillar. Some embodiments include a device isolation layer disposed on the substrate to surround a sidewall of the first doping layer. In some embodiments, the first doping layer is defined by doping first impurities on a portion of the substrate. Some embodiments provide that the first doping layer includes an epitaxial layer on the substrate. In some embodiments, the first doping layer includes a first diameter and the second doping layer includes a second diameter, and wherein the second diameter is greater than the first diameter. In some embodiments, the charge storage layer is configured to extend to surround the semiconductor pillar and to cover a top surface and a bottom surface of the control gate electrode.

Some embodiments include a tunneling insulating layer between the charge storage layer and the semiconductor pillar, and a blocking insulating layer between the charge storage layer and the control gate electrode. In some embodiments, the tunneling insulating layer and the blocking insulating layer are configured to extend to surround the semiconductor pillar and to cover a top surface and a bottom surface of the control gate electrode. In some embodiments, the semiconductor pillar includes a nano wire structure. Some embodiments include a bit line electrode that is electrically connected to the second doping layer.

Some embodiments of the present invention include a non-volatile memory device that includes a first doping layer on a substrate, the first doping layer including a first conductivity, a semiconductor pillar that is configured to extend from the first doping layer on the substrate in an upward direction, the semiconductor pillar including a second conductivity that is substantially opposite the first conductivity and a control gate electrode that is configured to surround a sidewall of the semiconductor pillar. Some embodiments may include a charge storage layer that is interposed between the semiconductor pillar and the control gate electrode, and that is configured to cover a top surface and a bottom surface of the control gate electrode and a second doping layer comprising the first conductivity, the second doping layer disposed on the semiconductor pillar and configured to be electrically connected to the semiconductor pillar. In some embodiments, the first doping layer is configured to cover a bottom surface of the semiconductor pillar.

Some embodiments of the present invention include methods of manufacturing a non-volatile memory device. Embodiments of such methods include forming a first doping layer having a first conductivity on a substrate, forming a semiconductor pillar having a second conductivity that is substantially opposite the first conductivity to extend from the first doping layer on the substrate in an upward direction, and forming a second doping layer having the first conductivity on the semiconductor pillar. Embodiments may include forming a charge storage layer surrounding a sidewall of the semiconductor pillar and forming a control gate electrode on a side of the charge storage layer that is substantially opposite the semiconductor pillar.

In some embodiments, the first doping layer is formed by doping a first conductive impurities on a portion of the substrate. In some embodiments, forming the first doping layer comprises performing an epitaxial deposition on the substrate. Some embodiments include forming a device isolation layer on the substrate that is configured to define the first doping layer. In some embodiments, forming the semiconductor pillar includes forming a nano wire structure. In some embodiments, forming the semiconductor pillar includes forming the semiconductor layer on the first doping layer using epitaxial deposition.

Methods according to some embodiments include forming a spacer insulating layer surrounding the sidewall of the semiconductor pillar before forming the second doping layer; and removing the spacer insulating layer after forming the second doping layer. In some embodiments, forming the spacer insulating layer includes thermally oxidizing the sidewall of the semiconductor pillar. In some embodiments, forming the charge storage layer includes covering the second doping layer and the semiconductor pillar and planarizing and/or anisotropically etching the charge storage layer to surround the semiconductor pillar and to cover a top surface and a bottom surface of the control gate electrode. Some embodiments include, after forming the second doping layer, forming a tunneling insulating layer interposed between the semiconductor pillar and the charge storage layer and forming a blocking insulating layer interposed between the charge storage layer and the control gate electrode. In some embodiments, the tunneling insulating layer and the blocking insulating layer are each formed to cover the second doping layer and the semiconductor pillar, and then are planarized and/or anisotropically etched to surround the semiconductor pillar and to cover the top surface and the bottom surface of the control gate electrode.

Some embodiments of the present invention include a semiconductor package that includes a semiconductor chip. The semiconductor chip may include non-volatile memory devices as described herein and may be attached on a substrate. Some embodiments provide that at least one solder ball may be attached to the substrate on the opposite side of the semiconductor chip and electrically connected to the semiconductor chip.

### BRIEF DESCRIPTION OF THE DRAWINGS

FIG. 1 is a partial perspective view of a non-volatile memory device according to some embodiments of the present invention.

FIG. 2 is a cross-sectional view of the non-volatile memory device of FIG. 1 taken along line II-II′, according to some embodiments of the present invention.

FIG. 3 is a cross-sectional view of the non-volatile memory device of FIG. 1 taken along line III-III′, according to some embodiments of the present invention.

FIGS. 4 through 9 are cross-sectional views illustrating methods of manufacturing a non-volatile memory device according to some embodiments of the present invention.

FIGS. 10 through 13 are cross-sectional views illustrating semiconductor packages according to some embodiments of the present invention.

FIG. 14 is a schematic view illustrating a card according to some embodiments of the present invention.

FIG. 15 is a block diagram illustrating a system according to some embodiments of the present invention.

### DETAILED DESCRIPTION OF THE INVENTION

The present invention will now be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

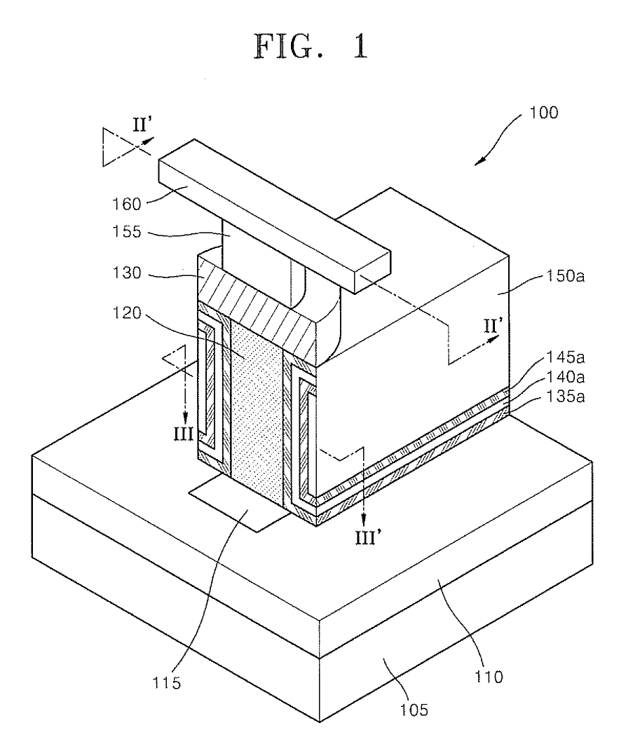

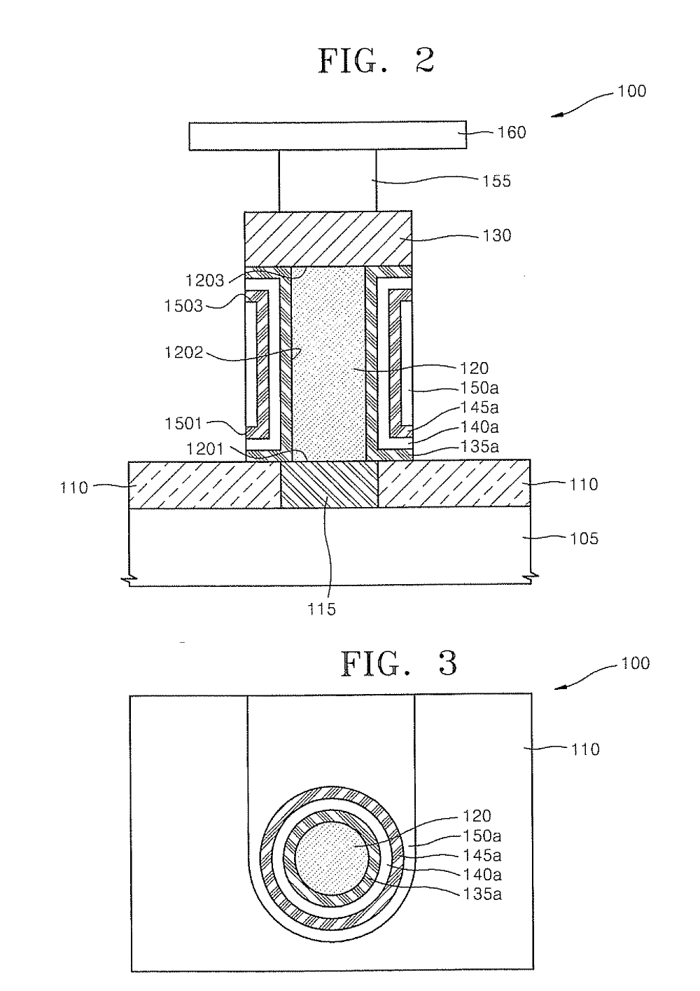

FIG. 1 is a partial perspective view of a non-volatile memory device 100 according to some embodiments of the present invention. FIG. 2 is a cross-sectional view of the non-volatile memory device 100 of FIG. 1 taken along line II-II′, according to some embodiments of the present invention. FIG. 3 is a cross-sectional view of the non-volatile memory device 100 of FIG. 1 taken along line III-III′, according to some embodiments of the present invention.

Referring to FIGS. 1 through 3, a semiconductor pillar 120 is interposed between a first doping layer 115 and a second doping layer 130. The first doping layer 115 and the second doping layer 130 have a first conductivity. The semiconductor pillar 120 has a second conductivity that is substantially opposite the first conductivity. In some embodiments, the first conductivity and the second conductivity may be n-type or p-type impurities, respectively. For example, the first doping layer 115 and the second doping layer 130 may be doped with first conductive impurities at a high density, and the semiconductor pillar 120 may be doped with second conductive impurities at a low density.

In some embodiments, the first doping layer 115 and the second doping layer 130 may respectively function as a source region and a drain region in a non-volatile memory device. In some embodiments, the first doping layer 115 and the second doping layer 130 may respectively function as the drain region and the source region. The semiconductor pillar 120 may define a channel region (not shown). Accordingly, in some embodiments, the semiconductor pillar 120 may electrically connect or disconnects the first and second doping layers 115 and 130 according to an on/off operation of the non-volatile memory device 100.

In some embodiments, the first doping layer 115 may be defined by doping first conductive impurities in a portion of a substrate 105 at a high density. The substrate 105 may be formed of a semiconductor material and may include a single crystalline structure. In some embodiments, the first doping layer 115 may be an epitaxial layer on the substrate 105. In the some embodiments, the first doping layer 115 is epitaxially formed according to the lattice of the substrate 105, and thus, may have the same crystalline structure as the substrate 105.

A device isolation layer 110 may surround sidewalls of the first doping layer 115. For example, in some embodiments, the device isolation layer 110 may include an oxide layer, a nitride layer and/or a low-k dielectric layer. The low-k dielectric layer may denote an insulating layer having a lower dielectric constant than an oxide layer.

In some embodiments, the semiconductor pillar 120 extends in an upward direction from the first doping layer 115 on the substrate 105 to the second doping layer 130. In this manner, the semiconductor pillar 120 may denote a semiconductor material arranged in the form of a pillar. In some embodiments, the semiconductor material includes silicon, silicon-germanium and/or germanium. The semiconductor pillar 120 may have a vertical structure according to some embodiments. In some embodiments, a the semiconductor pillar 120 may extend upward and obliquely from the substrate 105.

The semiconductor pillar 120 may have various forms. For example, in some embodiments the semiconductor pillar may be a nano wire structure formed of a semiconductor material. The nano wire may refer to a substantially linear material having a diameter in the nanometers scale. The nano wire may be used in nano-technology and may include a polygonal and/or circular cross-section. In FIG. 1, only half of the semiconductor pillar 120 is illustrated for convenience of explanation, however, in FIG. 3, a circular cross-section of the semiconductor pillar 120 is shown. In some embodiments, the diameter of the semiconductor pillar 120 may be fixed. In some embodiments, however, the semiconductor pillar 120 may be radially-shaped, with its diameter increasing upward.

In some embodiments, the semiconductor pillar 120 may be an epitaxial layer formed on the first doping layer 115 and include a bottom surface 1201, a sidewall 1202, and a top surface 1203. Some embodiments provide that the first doping layer 115 may cover at least a central portion of the bottom surface 1201 of the semiconductor pillar 120. In some embodiments, the first doping layer 115 may completely cover the bottom surface 1201 of the semiconductor pillar 120.

In some embodiments, the second doping layer 130 may be an epitaxial layer formed on the semiconductor pillar 120. Accordingly, the second doping layer 130, the semiconductor pillar 120, and the first doping layer 115 may include substantially the same crystalline structure, for example, a single crystalline structure. In some embodiments, the second doping layer 130 may cover the top surface 1203 of the semiconductor pillar 120.

In some embodiments, the second doping layer 130 may have a greater diameter than the semiconductor pillar 120 and the first doping layer 115. According to some embodiments, the diameter may refer to a length parallel to the substrate 105. For example, some embodiments may provide that the second doping layer 130 may have a radial structure, the diameter of which increases from the top surface 1203 of the semiconductor pillar 120 in an upward direction.

A control gate electrode 150a may surround the sidewall 1202 of the semiconductor pillar 120. The control gate electrode 150a may be disposed above the substrate 105 and may include a bottom surface 1501 and a top surface 1503. The control gate electrode 150a may be used as a portion of a word line.

A charge storage layer 140a may be interposed between the control gate electrode 150a and the semiconductor pillar 120. A tunneling insulating layer 135a may be interposed between the semiconductor pillar 120 and the charge storage layer 140a. A blocking insulating layer 145a may be interposed between the charge storage layer 140a and the control gate electrode 150a.

In some embodiments, the tunneling insulating layer 135a, the charge storage layer 140a and/or the blocking insulating layer 145a may surround the sidewall 1202 of the semiconductor pillar 120. Some embodiments may provide that the tunneling insulating layer 135a, the charge storage layer 140a, and/or the blocking insulating layer 145a extend further to cover the bottom surface 1501 and/or the top surface 1503 of the control gate electrode 150a. Some embodiments provide that the stack structure of the charge storage layer 140a and the blocking insulating layer 145a may be modified in various manners.

For example, in some embodiments, the tunneling insulating layer 135a and the blocking insulating layer 145a includes an oxide layer, a nitride layer and/or a high-k dielectric layer. The high-k dielectric layer may refer to an insulating layer having a greater dielectric constant than an oxide and/or a nitride. For example, the charge storage layer 140a may include a nitride layer, dots structure, and/or nanocrystals structure. The dots structure and the nanocrystals structure may include a conductive layer, including, for example, nano structures of metal and/or silicon, among others.

A bit line electrode 160 may be electrically connected to the second doping layer 130 through a contact plug 155. In some embodiments, the contact plug 155 may be disposed on the second doping layer 130 and the bit line electrode 160 may be disposed on the contact plug 155.

Non-volatile memory devices 100, as described herein, may be used as a data storage medium. In this manner, data can be programmed by storing charges in the charge storage layer 140a using a tunneling and/or a channel hot electron injection (CHEI) method. Additionally, data can be erased by tunneling in order to remove the charges of the charge storage layer 140a.

In some embodiments of non-volatile memory devices 100 as described herein, channels, which may be the conductive passage of charges, may be formed vertically along the semiconductor pillar 120. Accordingly, the length of the channels may be increased by controlling the height of the semiconductor pillar 120. As a result, the so-called short channel effect may be suppressed. In some embodiments, integration on of the substrate 105 can be increased by reducing the diameter towards the bottom surface 1201 of the semiconductor pillar 120. Accordingly, the non-volatile memory device 100 can have an increased integration degree and the short channel effect may be suppressed as compared to the conventional art. In this manner, non-volatile memory devices 100 according to embodiments described herein may reduce or eliminate a short channel effect that increases with the integration degree. In this regard, may provide advantages over conventional planar structures that may be susceptible the short channel effect.

Furthermore, some embodiments provide that the surface area of the charge storage layer 140a surrounding the semiconductor pillar 120 may be increased by controlling the height of the semiconductor pillar 120. As the surface area of the charge storage layer 140a increases, the amount of charges that can be stored to the charge storage layer 140a may be increased. Accordingly, the data programming and retention characteristics may be improved and the operational reliability of the non-volatile memory device 100 may be increased. Furthermore, the reliability of a multi-bit operation, in which data programming is performed by dividing the charge storage 140a into local parts, may be increased.

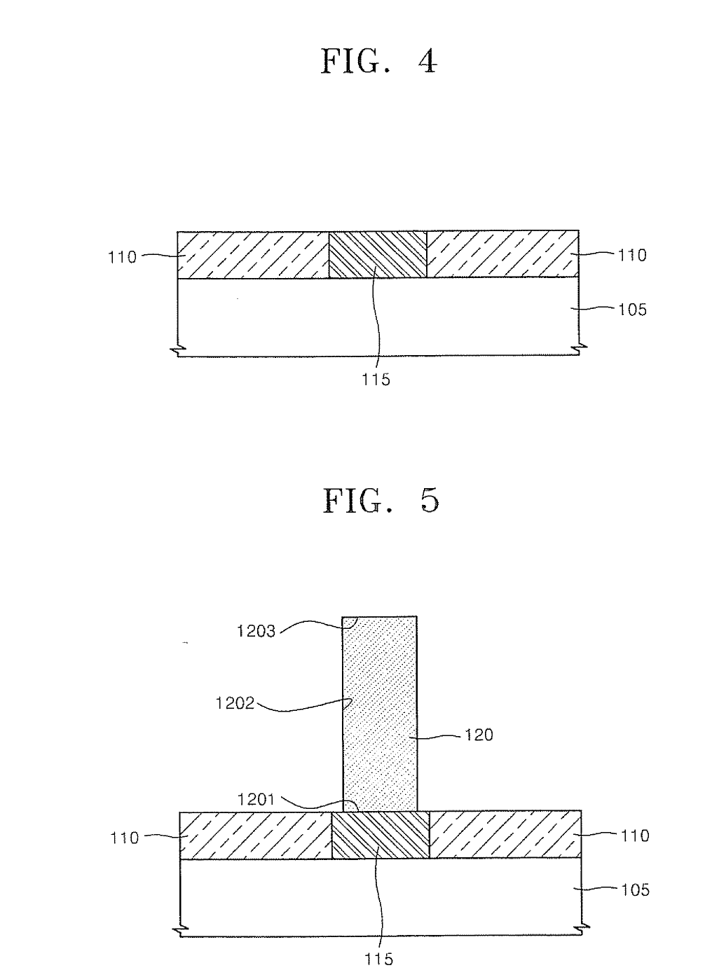

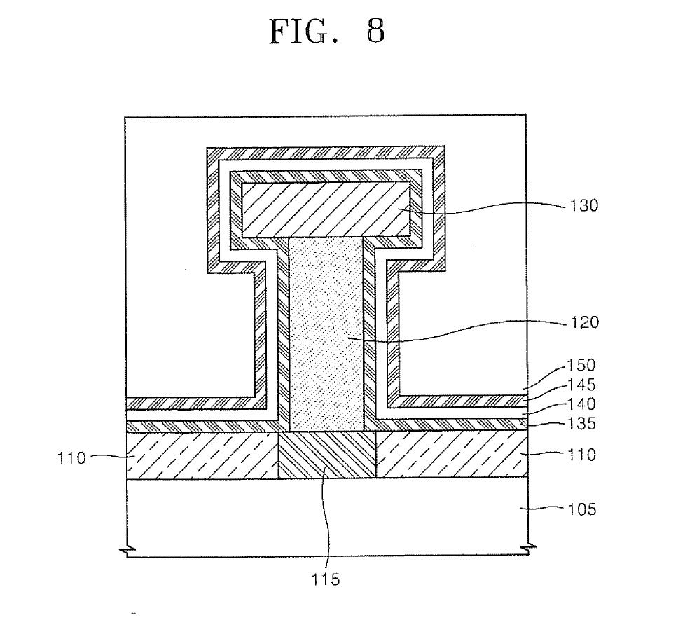

FIGS. 4 through 9 are cross-sectional views illustrating methods of manufacturing a non-volatile memory device, according to some embodiments of the present invention. Referring to FIG. 4, the first doping layer 115 may be formed on the substrate 105. In some embodiments, the device isolation layer 110 having a shallow trench structure may be formed on the substrate 105 to define the first doping layer 115. Before or after forming the device isolation layer 110, the first doping layer 115 may be doped with the first conductive impurities at a high density.

According to some embodiments, the first doping layer 115 is formed using an epitaxial deposition method. For example, some embodiments provide that a device isolation layer 110 may be formed on the substrate 105 and then the first doping layer 115 may be grown from the surface of the substrate 105 that is exposed through the device isolation layer 110. The first doping layer 115 may be doped with first conductive impurities at a high density during or after the epitaxial growth.

Referring to FIG. 5, a semiconductor pillar 120 may be formed and extend from the first doping layer 115 on the substrate 105 in an upward direction. The semiconductor pillar 120 may include a second conductivity that is different from the first conductivity. In some embodiments, the semiconductor pillar 120 may be grown on the first doping layer 115 using an epitaxial deposition method. The semiconductor pillar 120 may be doped with second conductive impurities at low density at the same time as or after the epitaxial growth.

Using the epitaxial deposition method, the semiconductor pillar 120 may not grow from the device isolation layer 110 and may be selectively grown from the first doping layer 115. However, growth in lateral directions may also be possible when using the epitaxial deposition method. Accordingly, in some embodiments, the semiconductor pillar 120 may have a radial structure with a diameter that increases in an upward direction. In some embodiments, by controlling the deposition conditions of the epitaxial deposition operation, the shape of the semiconductor pillar 120 may also be modified in various manners.

In some embodiments, the semiconductor pillar 120 can be grown as a nano wire structure of a semiconductor material using a molecular beam epitaxy (MBE) method and/or a ultra high vacuum chemical vapor deposition (UHVCVD) method, among others.

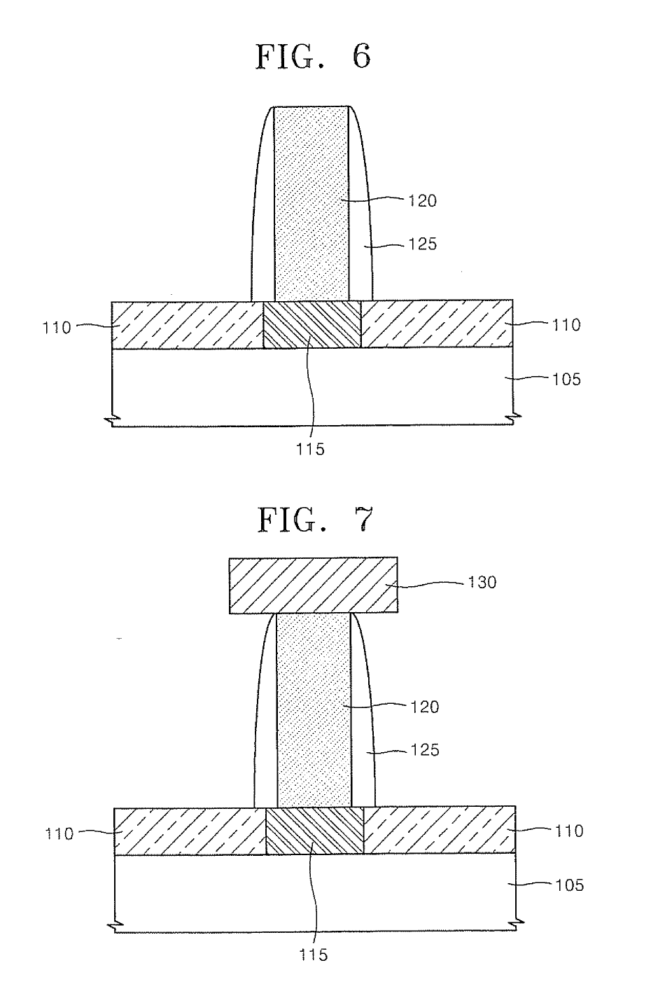

Referring to FIG. 6, a spacer insulating layer 125 may be formed on the sidewall 1202 of the semiconductor pillar 120. In some embodiments, the spacer insulating layer 125 may be formed by thermally oxidizing the sidewall 1202 of the semiconductor pillar 120. In some embodiments, the spacer insulating layer 125 may be formed by forming an oxide layer or a nitride layer on the sidewall 1202 of the semiconductor pillar 120 and then anisotropically etching the same.

Referring to FIG. 7, a second doping layer 130 having the first conductivity may be formed on the semiconductor pillar 120. The top surface 1203 of the semiconductor pillar 120 may be electrically connected to the second doping layer 130. In some embodiments, the second doping layer 130 may be grown from the semiconductor pillar 120 using an epitaxial deposition method. The spacer insulating layer 125 may prevent the semiconductor pillar 120 from growing on the sidewall 1202 of the semiconductor pillar 120. The semiconductor pillar 120 may be doped with the first conductive impurities at a high density at the same time with and/or after the epitaxial growth.

The second doping layer 130 may cover the top surface 1203 of the semiconductor pillar 120. The diameter of the second doping layer 130 may increase from the top surface 1203 of the semiconductor pillar 120 in an upward direction. Accordingly, the diameter of the second doping layer 130 may be greater than the diameter of the semiconductor pillar 120 and the first doping layer 115.

Referring to FIG. 5, a first material layer 135, a second material layer 140, a third material layer 145, and a fourth material layer 150 may be sequentially formed to surround the second doping layer 130 and the semiconductor pillar 120. In some embodiments, the first material layer 135 and the third material layer 145 include an insulating layer. The insulating layer may include, for example, an oxide layer, a nitride layer, and/or a high-k dielectric layer, among others. The second material layer 140 may include a nitride layer, a dot structure and/or a nanocrystal structure capable of charge trapping. The fourth material layer 150 may include a conductive layer including, for example, polysilicon, metal, and/or metal silicide, among others.

In some embodiments, the fourth material layer 150 includes a sufficiently large thickness to completely surround the semiconductor pillar 120. In some embodiments, the fourth material layer 150 includes a predetermined thickness that is configured to partially surround the semiconductor pillar 120.

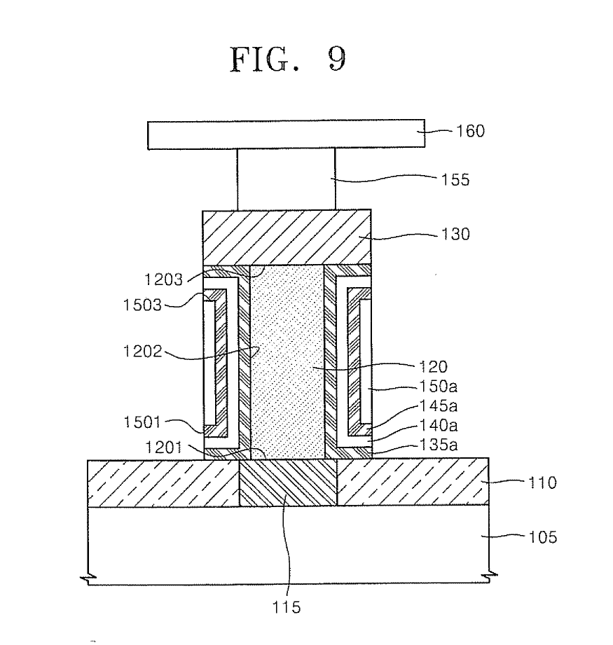

Referring to FIG. 9, the tunneling insulating layer 135a, the charge storage layer 140a, the blocking insulating layer 145a, and/or the control gate electrode 150a may be respectively formed by removing the first material layer 135, the second material layer 140, the third material layer 145, and/or the fourth material layer 150 on the second doping layer 130. In some embodiments, the first material layer 135, the second material layer 140, the third material layer 145, and/or the fourth material layer 150 may be planarized until the second doping layer 130 is exposed. The planarization may be performed using a chemical mechanical planarization (CMP) method and/or an etch-back method, among others.

Then, using a mask pattern (not shown), the tunneling insulating layer 135a, the charge storage layer 140a, the blocking insulating layer 145a, and/or the control gate electrode 150a may be patterned. In this manner, the tunneling insulating layer 135a, the charge storage layer 140a, the blocking insulating layer 145a, and/or the control gate electrode 150a may surround the semiconductor pillar 120 and may be defined under the second doping layer 130.

In some embodiments, the tunneling insulating layer 135a, the charge storage layer 140a, the blocking insulating layer 145a, and/or the control gate electrode 150a may be etched using the second doping layer 130 as an etching mask. In this case, the tunneling insulating layer 135a, the charge storage layer 140a, the blocking insulating layer 145a, and/or the control gate electrode 150a may include a shell structure surrounding the semiconductor pillar 120.

A contact plug 155 may be formed on the second doping layer 130. A bit line electrode 160 may be formed on the contact plug 155. The contact plug 155 and the bit line electrode 160 may include a conductive layer, for example, polysilicon, metal and/or metal silicide, among others.

Hereinafter, semiconductor packages 200a, 200b, 200c, and 200d according to some embodiments of the present invention will be described with reference to FIGS. 10 through 13. A semiconductor chip 205 corresponds to the non-volatile memory device 100 of FIGS. 1 through 3.

Referring to FIG. 10, the semiconductor chip 205 may be attached to a substrate 220 using, for example, solder bumps 210. One or more solder balls 230 are attached to the substrate 220 that is opposite to the semiconductor chip 205. The solder balls 230 may be electrically connected to the semiconductor chip 205 and function as an external terminal. A molding member 240 may be formed on the substrate 220 to cover the semiconductor chip 205. In some embodiments, the semiconductor package 200a may be referred to as a flip chip ball grid array (BGA).

In some embodiments, the semiconductor chip 205 in which the solder bumps 210 are formed may be directly mounted on a main board of an electric apparatus to realize a wafer level package (WLP).

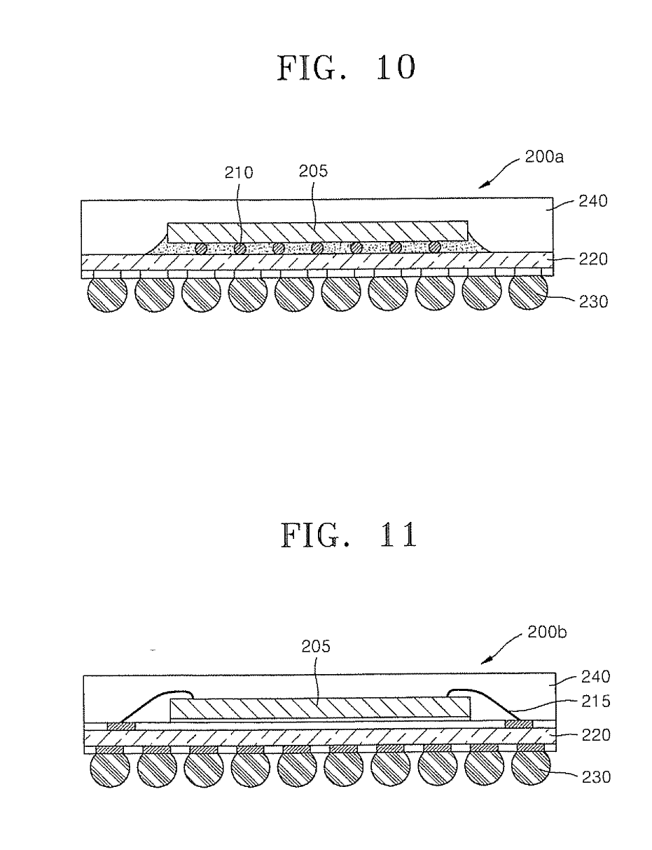

Referring to FIG. 11, the semiconductor chip 205 and the substrate 220 may be connected using a wire 215. Solder balls 230 may be connected to the substrate 220 that is opposite the semiconductor chip 205. In this manner, the semiconductor chip 205 may be electrically connected to the solder balls 230. The semiconductor package 200b including the above-described structure may be referred to as BGA structure.

Referring to FIG. 12, a semiconductor package 200c having a structure of a multi-chip package (MCP) may be manufactured by stacking a plurality of semiconductor chips 205 on a substrate 220. In some embodiments, the semiconductor chips 205 may have the same structure or different structures from each other. For example, some of the semiconductor chips 205 may have the same structure as the non-volatile memory device 100 or 100a, and other of the semiconductor chips 205 may have different structures.

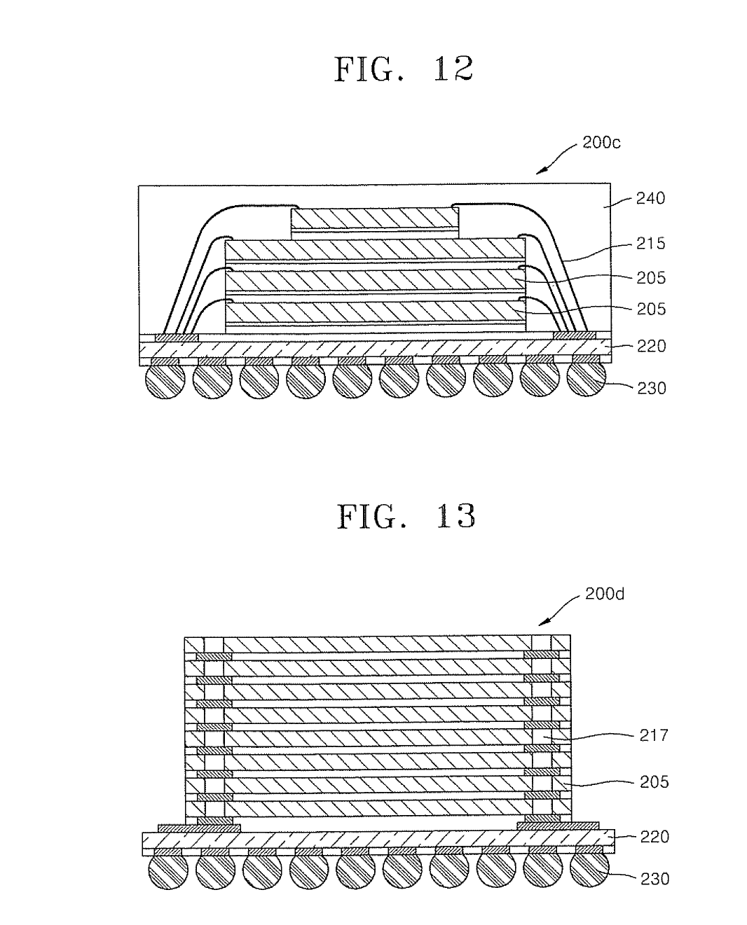

Referring to FIG. 13, a plurality of semiconductor chips 205 may be stacked on a substrate 220, and through vias 217 may be formed in the semiconductor chips 205. In this manner, a stack type semiconductor package 200d may be manufactured. The semiconductor chips 205 can be electrically connected to the solder balls 230 via the substrate 220 using the through vias 217.

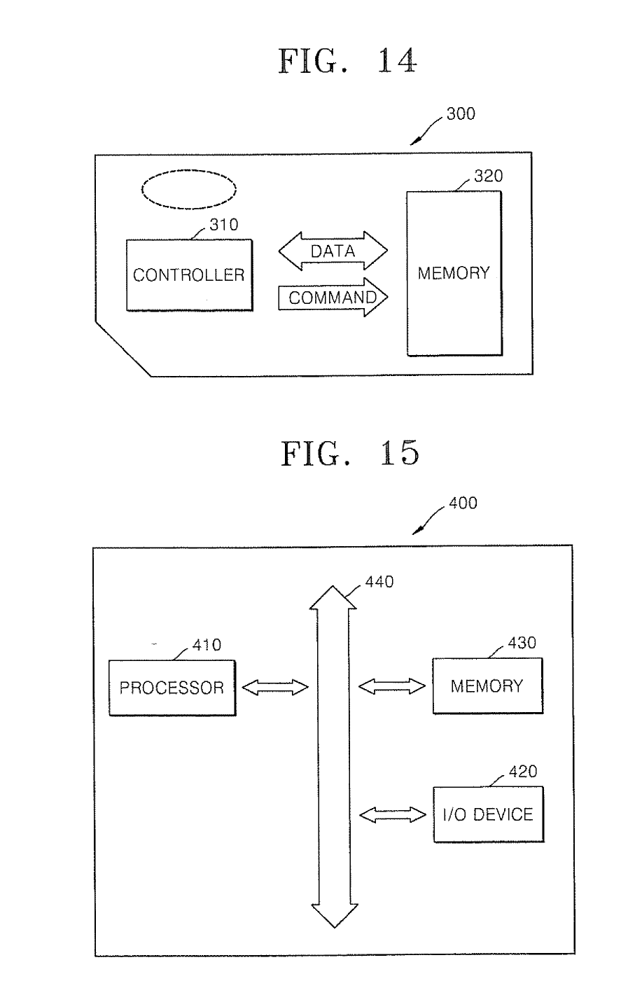

Referring to FIG. 14, which is a schematic view of a card 300 according to some embodiments of the present invention, a controller 310 and a memory 320 may be disposed to exchange electric signals. For example, when the controller 310 gives a command, the memory 320 can send data responsive to the command. The memory 320 may correspond to a non-volatile memory device 100 as illustrated in FIGS. 1 through 3. The card 300 may be used for a memory device such as, for example, a multi media card (MMC) and/or a secure digital card (SD), among others.

In some embodiments, the non-volatile memory device 100 may be connected to a main substrate in a chip structure using wire bonding and/or solder bumps. In some embodiments, the non-volatile memory device 100 may be directly connected to the controller 310. In some embodiments, the non-volatile memory device 100 may be manufactured as one of the above-described semiconductor packages 200a, 200b, 200c, and 200d or to be similar to these packages, and mounted on a main board.

Reference is now made to FIG. 15, which is a block diagram illustrating a system 400 according to some embodiments of the present invention. A processor 410, an input/output apparatus 420, and a memory 430 can perform data communication using a bus 440. The processor 410 may perform programming and controls the system 400. The input/output apparatus 420 may be used to input or output data of the system 400. The memory 430 may correspond to the non-volatile memory device 100 illustrated in FIGS. 1 through 3, among others. In some embodiments, the memory 430 may store codes and data for operating the processor 410.

In some embodiments, the system 400 may be connected to an external apparatus, for example, to a personal computer or a network, using the input/output apparatus 420. In this manner, the system 400 may exchange data with the external apparatus. In some embodiments, the system 400 may include a mobile phone, a MP3 player, a navigation device, a solid state disk (SSD) and/or a household appliance, among others.

In a some embodiments of non-volatile memory device, a channel length can be increased by controlling the height of a semiconductor pillar. In some embodiments, by reducing the diameter of the semiconductor pillar, the integration degree on the substrate may be increased. Accordingly, the non-volatile memory device can have an increased integration degree and a short channel effect may be suppressed at the same time.

In some embodiments of a non-volatile memory device as disclosed herein, the surface area of a charge storage layer surrounding the semiconductor pillar can be increased by controlling the height of the semiconductor pillar. In this manner, the data programming and retention characteristics may be improved. Accordingly, the operation reliability of the non-volatile memory device may be increased. In addition, the reliability of a multi-bit operation, which programs data by dividing the charge storage layer into local parts, may be increased.

Although the present invention has been described in terms of specific embodiments, the present invention is not intended to be limited by the embodiments described herein. Thus, the scope may be determined by the following claims.

1. A non-volatile memory device comprising:
a first doping layer on a substrate, the first doping layer having a first conductivity type;
a semiconductor pillar that is configured to extend from the first doping layer on the substrate in an upward direction, the semiconductor pillar having a second conductivity type that is substantially opposite the first conductivity type;
a control gate electrode surrounding a sidewall of the semiconductor pillar;
a charge storage layer interposed between the semiconductor pillar and the control gate electrode; and
a second doping layer that is disposed on the semiconductor pillar and that is configured to be electrically connected to the semiconductor pillar, the second doping layer having the first conductivity type.

2. The non-volatile memory device of claim 1, wherein the first doping layer covers at least a central portion of a bottom surface of the semiconductor pillar.

3. The non-volatile memory device of claim 1, wherein the first doping layer surrounds a bottom surface of the semiconductor pillar.

4. The non-volatile memory device of claim 1, further comprising a device isolation layer disposed on the substrate to surround a sidewall of the first doping layer.

5. The non-volatile memory device of claim 1, wherein the first doping layer is defined by doping first impurities on a portion of the substrate.

6. The non-volatile memory device of claim 1, wherein the first doping layer comprises an epitaxial layer on the substrate.

7. The non-volatile memory device of claim 1, wherein the first doping layer comprises a first diameter and the second doping layer comprises a second diameter, and wherein the second diameter is greater than the first diameter.

8. The non-volatile memory device of claim 7, wherein the charge storage layer is configured to extend to surround the semiconductor pillar and to cover a top surface and a bottom surface of the control gate electrode.

9. The non-volatile memory device of claim 1, further comprising a tunneling insulating layer between the charge storage layer and the semiconductor pillar, and a blocking insulating layer between the charge storage layer and the control gate electrode.

10. The non-volatile memory device of claim 9, wherein the tunneling insulating layer and the blocking insulating layer are configured to extend to surround the semiconductor pillar and to cover a top surface and a bottom surface of the control gate electrode.

11. The non-volatile memory device of claim 1, wherein the semiconductor pillar comprises a nano wire structure.

12. The non-volatile memory device of claim 1, further comprising a bit line electrode that is electrically connected to the second doping layer.

13. A non-volatile memory device comprising:
a first doping layer on a substrate, the first doping layer having a first conductivity type;
a semiconductor pillar that is configured to extend from the first doping layer on the substrate in an upward direction, the semiconductor pillar having a second conductivity type that is substantially opposite the first conductivity type;
a control gate electrode that is configured to surround a sidewall of the semiconductor pillar;
a charge storage layer that is interposed between the semiconductor pillar and the control gate electrode, and that is configured to cover a top surface and a bottom surface of the control gate electrode; and
a second doping layer having the first conductivity type, the second doping layer disposed on the semiconductor pillar and configured to be electrically connected to the semiconductor pillar.

14. The non-volatile memory device of claim 13, wherein the first doping layer is configured to cover a bottom surface of the semiconductor pillar.

15. A method of manufacturing a non-volatile memory device, the method comprising:
forming a first doping layer having a first conductivity on a substrate;
forming a semiconductor pillar having a second conductivity that is substantially opposite the first conductivity to extend from the first doping layer on the substrate in an upward direction;
forming a second doping layer having the first conductivity on the semiconductor pillar;
forming a charge storage layer surrounding a sidewall of the semiconductor pillar; and
forming a control gate electrode on a side of the charge storage layer that is substantially opposite the semiconductor pillar.

16. The method of claim 15, wherein forming the first doping layer comprises doping a portion of the substrate using first conductive impurities.

17. The method of claim 15, wherein forming the first doping layer comprises performing an epitaxial deposition on the substrate.

18. The method of claim 15, further comprising forming a device isolation layer on the substrate that is configured to define the first doping layer.

19. The method of claim 15, wherein forming the semiconductor pillar comprises forming a nano wire structure.

20-25. (canceled)

26. A semiconductor package comprising:
a semiconductor chip including the non-volatile memory device of claim 1 and attached on a substrate; and
at least one solder ball attached to the substrate on the opposite side of the semiconductor chip and electrically connected to the semiconductor chip.
